(19) United States
(12) Patent Application Publication
(10) Pub. No.: US 2012/0161249 A1
(43) Pub. Date: Jun. 28, 2012

(54) Reduction of Defect Rates in PFET Transistors Comprising a Silicon/Germanium Semiconductor Material by Providing a Graded Germanium Concentration

(75) Inventors: Stephan-Detlef Kronholz, Dresden (DE); Ina Ostermay, Berlin (DE); Roman Boschke, Dresden (DE)

(73) Assignee: GLOBALFOUNDRIES Inc., Grand Cayman (KY)

(21) Appl. No.: 13/338,349

(22) Filed: Dec. 28, 2011

(30) Foreign Application Priority Data
Dec. 28, 2010 (DE) 10 2010 064 280.0

(51) Int. Cl. H01L 29/772; H01L 21/336

(52) U.S. Cl. 257/402; 438/285; 257/E21.409; 257/E29.242

(57) ABSTRACT

When forming sophisticated gate electrode structures in an early manufacturing stage, the threshold voltage characteristics may be adjusted on the basis of a semiconductor alloy, which may be formed on the basis of low pressure CVD techniques. In order to obtain a desired high band gap offset, for instance with respect to a silicon/germanium alloy, a moderately high germanium concentration may be provided within the semiconductor alloy, wherein, however, at the interface formed with the semiconductor base material, a low germanium concentration may significantly reduce the probability of creating dislocation defects.

### BACKGROUND OF THE INVENTION

1. Field of the Invention

Generally, the present disclosure relates to integrated circuits, and, more particularly, to transistors comprising an epitaxially grown silicon/germanium mixture in the active regions of the transistors.

2. Description of the Related Art

The fabrication of complex integrated circuits requires the provision of a large number of transistor elements, which represent the dominant circuit elements in complex integrated circuits. For example, several hundred millions of transistors may be provided in presently available complex integrated circuits, wherein performance of the transistors in the speed critical signal paths substantially determines overall performance of the integrated circuit. Generally, a plurality of process technologies are currently practiced, wherein, for complex circuitry, such as microprocessors, storage chips and the like, CMOS technology is currently the most promising approach due to the superior characteristics in view of operating speed and/or power consumption and/or cost efficiency. In CMOS circuits, complementary transistors, i.e., P-channel transistors and N-channel transistors, are used for forming circuit elements, such as inverters and other logic gates to design highly complex circuit assemblies, such as CPUs, storage chips and the like. During the fabrication of complex integrated circuits using CMOS technology, millions of transistors, i.e., N-channel transistors and P-channel transistors, are formed on a substrate including a crystalline semiconductor layer. A MOS transistor or generally a field effect transistor, irrespective of whether an N-channel transistor or a P-channel transistor is considered, comprises so-called PN junctions that are formed by an interface positioned between highly doped drain and source regions and an inversely or weakly doped channel region disposed between the drain region and the source region. The conductivity of the channel region, i.e., the drive current capability of the conductive channel, is controlled by a gate electrode formed in the vicinity of the channel region and separated therefrom by a thin insulating layer. The conductivity of the channel region, upon formation of a conductive channel due to the application of an appropriate control voltage to the gate electrode, depends on, among other things, the mobility of the charge carriers and, for a given extension of the channel region in the transistor width direction, on the distance between the source and drain regions, which is also referred to as channel length. Thus, the reduction of the channel length, and associated therewith the reduction of the channel resistivity, is a dominant design criterion for accomplishing an increase in the operating speed of the integrated circuits.

Upon continuously reducing the channel length of field effect transistors, generally an increased degree of capacitive coupling is required in order to maintain controllability of the channel region, which may typically require an adaptation of a thickness and/or material composition of the gate dielectric material. For example, for a gate length of approximately 80 nm, a gate dielectric material based on silicon dioxide with a thickness of less than 2 nm may be required in high speed transistor elements, which may, however, result in increased leakage currents caused by hot carrier injection and direct tunneling of charge carriers through the extremely thin gate dielectric material. Since a further reduction in thickness of silicon dioxide-based gate dielectric materials may increasingly become incompatible with thermal power requirements of sophisticated integrated circuits, other alternatives have been developed in increasing the charge carrier mobility in the channel region, thereby also enhancing overall performance of field effect transistors. One promising approach in this respect is the generation of a certain type of strain in the channel region, since the charge carrier mobility in silicon strongly depends on the strain conditions of the crystalline material. For example, for a standard crystallographic configuration of the silicon-based channel region, a compressive strain component in a P-channel transistor may result in a superior mobility of holes, thereby increasing switching speed and drive current of P-channel transistors. The desired compressive strain component may be obtained according to well-established approaches by incorporating a strain-inducing semiconductor material, for instance in the form of a silicon/germanium mixture or alloy, in the active region of the P-channel transistor. For example, after forming the gate electrode structure, corresponding cavities may be formed laterally adjacent to the gate electrode structure in the active region and may be refilled with the silicon/germanium alloy which, when grown on the silicon material, may have an internal strained state, which in turn may induce a corresponding compressive strain component in the adjacent channel region. Consequently, a plurality of process strategies have been developed in the past in order to incorporate a highly strained silicon/germanium material in the drain and source areas of P-channel transistors.

In other approaches, the inferior controllability of the channel region of the short channel transistors caused by the continuous reduction of the critical dimensions of gate electrode structures has been addressed by an appropriate adaptation of the material composition of the gate dielectric material. To this end, it has been proposed that, for a physically appropriate thickness of a gate dielectric material, i.e., for reducing the gate leakage currents, a desired high capacitive coupling may be achieved by using appropriate material systems, which have a significantly higher dielectric constant compared to the conventionally used silicon dioxide-based materials. For example, dielectric materials including hafnium, zirconium, aluminum and the like may have a significantly higher dielectric constant and are, therefore, referred to as high-k dielectric materials, which are to be understood as materials having a dielectric constant of 10.0 or higher when measured in accordance with typical measurement techniques. As is well known, the electronic characteristics of the transistors also strongly depend on the work function of the gate electrode material, which in turn influences the band structure of the semiconductor material in the channel regions separated from the gate electrode material by the gate dielectric layer. In well-established polysilicon/silicon dioxide-based gate electrode structures, the corresponding threshold voltage, that is strongly influenced by the gate dielectric material and the adjacent electrode material, is adjusted by appropriately doping the polysilicon material in order to appropriately adjust the work function of the polysilicon material at the interface between the gate dielectric material and the electrode material. Similarly, in gate electrode structures including a high-k gate dielectric material, the work function has to be appropriately adjusted for N-channel transistors and P-channel transistors, respectively, which may require appropriately selected work function adjusting metal species, such as lanthanum for N-channel transistors and aluminum for P-channel transistors and the like. For this reason, corresponding metal-containing conductive materials may be positioned close to the high-k gate dielectric material in order to form an appropriately designed interface that results in the target work function of the gate electrode structure. In some conventional approaches, the work function adjustment is performed at a very late manufacturing stage, i.e., after any high temperature processes, after which a placeholder material of the gate electrode structures, such as polysilicon, is replaced by an appropriate work function adjusting species in combination with an electrode metal, such as aluminum and the like. In this case, however, very complex patterning and deposition process sequences are required in the context of gate electrode structures having critical dimensions of 50 nm and significantly less, which may result in severe variations of the resulting transistor characteristics.

Therefore, other process strategies have been proposed in which the work function adjusting materials may be applied in an early manufacturing stage, i.e., upon forming the gate electrode structures, wherein the metal species may be thermally stabilized and encapsulated in order to obtain the desired work function and thus threshold voltage of the transistors without being unduly influenced by the further processing. It turns out that, for any appropriate metal species and metal-containing electrode materials, an appropriate adaptation of the band gap of the channel semiconductor material may be required, for instance in the P-channel transistors, in order to appropriately set the work function thereof. For this reason, frequently, a so-called threshold adjusting semiconductor material, for instance in the form of a silicon/germanium mixture, is formed on the active regions of the P-channel transistors prior to forming the gate electrode structures, thereby obtaining the desired offset in the band gap of the channel semiconductor material. The electronic characteristics, and in particular the threshold voltage, of the P-channel transistors, thus, strongly depends on the characteristics of the silicon/germanium mixture, i.e., on the material composition and the layer thickness, as well as on the uniformity of these parameters, so that complex selective epitaxial growth techniques are typically required in order to form the silicon/germanium mixture with uniform and predefined characteristics.

Consequently, in sophisticated semiconductor devices, a silicon/germanium material may have to be provided with precisely defined characteristics, for instance, as explained before for appropriately adjusting the band gap offset of the channel material, while in other cases, additionally or alternatively, a silicon/germanium material may have to be provided as an embedded strain-inducing material, wherein the characteristics of the embedded semiconductor material may also strongly affect performance of the transistors. Although these process techniques may provide significant advantages, for instance in view of reducing overall process complexity, for instance in view of replacement gate approaches or in view of enhancing overall performance, it turns out, however, that the material composition and layer thickness of an epitaxially grown silicon/germanium material may not be arbitrarily selected without significantly influencing the finally achieved transistor characteristics, as will be described in more detail with reference to FIGS. 1a-1c.

FIG. 1a schematically illustrates a cross-sectional view of a semiconductor device in which a silicon/germanium material is to be provided in the channel area of one type of transistor on the basis of an epitaxial growth process. In the manufacturing stage shown, the device 100 comprises a substrate 101 and a silicon-based semiconductor layer 102, wherein the substrate 101 and the semiconductor layer 102 form a bulk configuration or a silicon-on-insulator (SOI) configuration, depending on the desired transistor architecture. For example, for an SOI configuration, a buried insulating layer (not shown) is formed below the semiconductor layer 102 and thus isolates the layer 102 with respect to the substrate 101. The semiconductor layer 102 further comprises isolation structures 102C, such as shallow trench isolations, which laterally delineate semiconductor regions or active regions, two of which, indicated as 102A, 102B, are illustrated in FIG. 1a. In the example shown, the active region 102A corresponds to the semiconductor region of a P-channel transistor, while the active region 102B corresponds to an N-channel transistor. An appropriate mask layer 103, such as a silicon dioxide material, may be formed on the active region 102B in order to act as a deposition mask for the selective epitaxial growth of a silicon/germanium material in the active region 102A. In some illustrative approaches, typically a recess 102R is provided in the region 102A prior to actually depositing the silicon/germanium material.

The semiconductor device 100 as illustrated in FIG. 1a may be formed on the basis of the following processes. The isolation structure 102C may be formed by using sophisticated lithography, etch, deposition and planarization techniques, wherein, prior to or after forming the isolation structure 102C, appropriate well dopant species may be incorporated into the active regions 102A, 102B in order to define the basic transistor characteristics. To this end, any well-established implantation techniques and masking regimes may be applied. Thereafter, the mask 103 is formed, for instance by oxidation, deposition and the like, wherein a non-desired portion of the mask material is removed from above the active region 102A, for instance by applying a resist mask and performing any appropriate etch process. Furthermore, as illustrated, the recess 102R may be formed with an appropriate depth so as to obtain a desired surface topography after the deposition of the silicon/germanium material. Next, a selective epitaxial growth process is performed after any cleaning processes and the like in which process parameters are established in such as manner that a significant semiconductor material deposition is substantially restricted to exposed surface areas of the active region 102A, while any pronounced deposition on dielectric surface areas, such as the mask 103 and the isolation structure 102C, is suppressed. To this end, well-established chemical vapor deposition (CVD) techniques with process temperatures in the range of 650-750° C. have been developed on the basis of appropriately selected gas flow rates and process pressures, wherein the fraction of germanium in the silicon/germanium mixture may be set on the basis of controlling the corresponding gas flow rates. As previously explained, the resulting electronic characteristics, in particular the resulting threshold voltage, may significantly depend on the thickness of the silicon/germanium material and the material composition thereof, i.e., the germanium fraction contained therein. For example, a thickness of approximately 8-12 nm and a germanium content of up to 25 percent may be used in order to obtain the required threshold voltage.

FIG. 1b schematically illustrates the semiconductor device 100 in a further advanced manufacturing stage. As illustrated, a silicon/germanium mixture or alloy 104 is formed in the active region 102A and thus represents a portion thereof, thereby providing the desired band gap offset, as discussed above. Furthermore, a gate electrode structure 160A of a P-channel transistor 150A is formed on the channel material 104 and may comprise a gate dielectric material 163A and a metal-containing electrode material 162A, followed by a further electrode material 161, such as silicon and the like. Furthermore, the materials 163A, 162A, 161 may be encapsulated by a spacer structure 165, for instance provided in the form of a silicon nitride material and the like, while also a cap layer 164 may be provided, for instance in the form of silicon dioxide, silicon nitride and the like. Similarly, a gate electrode structure 160B of an n-channel transistor 150B may be formed on the active region 102B and may have basically a similar configuration as the gate electrode structure 160A. That is, a gate dielectric material 163B in combination with a metal-containing electrode material 162B and the electrode material 161 may be provided in combination with the spacer structure 165 and a cap layer 164. It should be appreciated that the gate dielectric material 163A, 163B may have basically the same configuration and may, however, differ in a work function adjusting species that may have been incorporated therein during the previous processing. For example, frequently, appropriate species may be diffused into the gate dielectric material in order to appropriately modify the characteristics thereof in view of achieving a desired overall work function and thus threshold voltage. Moreover, as discussed above, the gate dielectric layers 163A, 163B comprise a high-k dielectric material, such as hafnium oxide and the like, possibly in combination with a thin conventional dielectric material, for instance in the form of silicon oxynitride and the like, in view of superior interface characteristics. The metal-containing electrode material 162A, 162B may have substantially the same composition or may also differ with respect to a work function adjusting species, depending on the overall process strategy applied for forming the gate electrode structures 160A, 160B.

A typical process flow for forming the semiconductor device 100 as illustrated in FIG. 1b may comprise the following processes. First, the basic material composition of the gate dielectric layers 163A, 163B may be provided, possibly in combination with any work function adjusting metal species and additional cap materials, such as titanium nitride and the like, and any appropriate treatment, such as anneal processes and the like, may be applied in order to adjust the overall characteristics of the gate dielectric materials 163A, 163B. Thereafter, the same or different materials may be deposited for the layers 162A, 162B, followed by the deposition of the material 161, for instance in the form of amorphous or polycrystalline silicon. Moreover, any further material such as the cap material 164 is provided and the resulting layer stack is patterned on the basis of sophisticated lithography and etch techniques. Thereafter, the spacer structure 165 is formed by any appropriate deposition and etch strategy in order to confine, in particular, the sensitive materials 163A, 163B and 162A, 162B.

Consequently, by means of the channel material 104, an appropriate threshold voltage for the transistor 150A could, in principle, be obtained, wherein, however, significant defects have been observed in the material 104, as indicated by 104A, when the material 104 is provided with a thickness and material composition, as specified above. For example, defect values of 200,000 and more defects per cm² have been identified upon performing corre-sponding defect etch experiments. However, corresponding defects in the channel region of the transistor 150A may result in significant variation of transistor characteristics or may even result in a non-acceptable transistor performance.

FIG. 1c schematically illustrates the semiconductor device 100 in a further advanced manufacturing stage. As shown, the transistor 150A comprises the gate electrode structure 160A, possibly with an additional spacer structure 166, which may include the spacer structure 165 (FIG. 1b). The spacer structure 166 may be used for defining the lateral and vertical dopant profile of drain and source regions 152. Similarly, the transistor 150B comprises the gate electrode structure 160B and corresponding drain and source regions 152, which, however, have an inverse conductivity type compared to the regions 152 of the transistor 150A. The transistors 150A, 150B may be formed on the basis of any appropriate process strategy for providing the spacer structure 166 and the drain and source regions 152. Thus, as illustrated, a channel region 151 comprising the silicon/germanium material 104 may have an inferior performance due to the high number of defects 104A, as discussed above. Basically, the defect rate could be reduced, for instance, by reducing the fraction of germanium material in the layer 104 and/or by reducing the thickness thereof, which, however, in turn would result in significantly changed threshold voltages, which, however, may not be compatible with the overall design of the transistor 150A.

As a consequence, although the above-described process strategy may provide a promising approach for defining the basic transistor characteristics, such as the work function and thus threshold voltage of sophisticated transistors in an early manufacturing stage, the resulting high defect rate of the silicon/germanium material may cause significant device failures due to corresponding dislocation defects, which may insignificantly increase in number and size when the germanium concentration is to be increased to a level of about 25 atomic percent and higher in order to appropriately adjust the threshold voltage of the P-channel transistors. Reducing the thickness of the silicon/germanium layer in order to reduce the number of dislocation defects, however, is not a viable solution, since a reduction in thickness may also significantly affect the resulting threshold voltage, thereby offsetting the effect of increasing the germanium concentration.

In view of the situation described above, the present disclosure relates to process techniques and semiconductor devices in which sophisticated high-k metal gate electrode structures may be formed in an early manufacturing stage on the basis of a threshold adjusting semiconductor alloy, while avoiding or at least reducing the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

The present disclosure generally provides semiconductor devices and manufacturing techniques in which the electronic characteristics of a channel region of a complex field effect transistor may be adjusted by providing a specifically configured semiconductor alloy, such as a silicon/germanium alloy, wherein the number of any significant lattice defects, such as dislocations, may be significantly reduced by implementing a graded concentration profile through the thickness of the semiconductor alloy. That is, the threshold adjusting semiconductor alloy may be provided so as to have a reduced lattice mismatch relative to the semiconductor base material of the active region under consideration so that, at the interface formed between the threshold adjusting semiconductor material and the silicon base material, the growth of the semiconductor alloy may be initiated without a significant probability of creating any lattice defects. For example, the growth conditions may be adjusted such that an initial percentage of the actual lattice mismatch generating atomic species, such as the germanium species in a silicon/germanium material, may be 10 atomic percent or significantly less, depending on the type of atomic species under consideration. For example, if a semiconductor alloy including atomic species of significant different covalent radius have to be deposited, any appropriate concentration of less than 10 atomic percent may be used at an initial phase of the growth process. Thereafter, the concentration of the atomic species of the semiconductor alloy may be appropriately adapted so as to obtain a graded or varying concentration profile so as to finally achieve the desired composition of the semiconductor alloy at a top surface thereof. Consequently, by setting the initial and final concentration value for the alloy species and by adjusting the corresponding concentration gradient, not only superior lattice quality may be obtained, but also a high degree of flexibility is achieved in adjusting the resulting threshold voltage of the transistor under consideration. Consequently, by implementing a graded concentration profile, the growth conditions at any phase of the epitaxial growth process may be maintained in a state in which creation of any lattice defects may be reduced since, for instance, the corresponding layer thickness and/or concentration at each individual growth phase may be maintained at non-critical values, which may thus ensure a high crystalline quality of the grown semiconductor alloy.

One illustrative method disclosed herein comprises forming a crystalline silicon/germanium-containing material on a silicon material of an active region of a P-channel transistor so as to have a graded germanium concentration. The method further comprises forming a gate electrode structure on the crystalline silicon/germanium-containing material, wherein the gate electrode structure comprises a gate dielectric material that separates an electrode material of the gate electrode structure from a channel region in the crystalline silicon/germanium-containing material. Furthermore, the method comprises forming drain and source regions of the P-channel transistor in the active region.

A further illustrative method disclosed herein relates to forming a semiconductor device. The method comprises forming a hard mask so as to expose an active region of a first transistor and cover an active region of a second transistor. The method further comprises performing a selective epitaxial growth process so as to form a threshold adjusting semiconductor alloy on the active region of the first transistor with a first lattice mismatch at an interface that is formed with a surface of the active region of the first transistor and with a second lattice mismatch at a top surface of the threshold adjusting semiconductor alloy, wherein the first lattice mismatch is less than the second lattice mismatch. The method further comprises forming a first gate electrode structure on the threshold adjusting semiconductor alloy and forming a second gate electrode structure on the active region of the second transistor.

One illustrative field effect transistor disclosed herein comprises an active region formed above a substrate and comprising a doped semiconductor base material and a threshold adjusting semiconductor alloy. The threshold adjusting semiconductor alloy forms an interface with the semiconductor base material and has a top surface wherein a first atomic species and a second atomic species of the threshold adjusting semiconductor alloy have a varying concentration between the interface and the top surface. The field effect transistor further comprises a gate electrode structure that is formed on the threshold adjusting semiconductor material and that comprises a high-k dielectric material. Moreover, the transistor comprises drain and source regions formed in the active region.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1c schematically illustrate a sophisticated semiconductor device in which the threshold voltage of a P-channel transistor is adjusted in an early manufacturing stage on the basis of a silicon/germanium alloy, above which is formed a high-k metal gate electrode structure; and

FIGS. 2a-2e schematically illustrate cross-sectional views of a semiconductor device during various manufacturing stages in which complex field effect transistors are formed, some of which receive a threshold adjusting semiconductor material having a graded concentration profile in order to reduce any lattice defects, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally provides semiconductor devices and manufacturing techniques in which a semiconductor alloy, such as a silicon/germanium alloy, may be incorporated in the active region of specific transistors, such as P-channel transistors, wherein a significantly reduced number of lattice defects may be achieved, which may be accomplished by providing the semiconductor alloy with a varying or graded concentration profile. In this respect, a varying or graded concentration profile is to be understood as any “vertical” profile of a concentration of the alloy-forming species under consideration, wherein the concentration at one surface or interface differs from the concentration determined at least at one intermediate position, i.e., one intermediate layer, throughout the thickness of the semiconductor alloy. For example, concentration values of the alloy-forming species may be different in corresponding oppositely located interfaces or surfaces of the layer under consideration, while, in other cases, a concentration maximum may be positioned at any intermediate location throughout the thickness of the semiconductor alloy. For example, in some illustrative embodiments disclosed herein, the concentration of the semiconductor alloy may vary such that the degree of a lattice mismatch at an interface formed between the semiconductor base material and the semiconductor alloy may be less compared to the lattice mismatch at the oppositely positioned surface or interface. In this respect, a lattice mismatch is to be understood as the difference of the natural, i.e., relaxed, lattice states of the semiconductor material under consideration. For example, if a silicon base material is provided in the active region and the semiconductor alloy to be formed thereon is a silicon/germanium alloy, generally the natural lattice constant of the silicon/germanium material is greater compared to the natural lattice constant of silicon, thereby obtaining a certain lattice mismatch, wherein the magnitude of the mismatch increases with an increase of the germanium concentration, which is the alloy-forming species having the greater covalent radius compared to the silicon species of the semiconductor base material. Typically, an increased lattice mismatch is correlated with an increase of corresponding dislocation defects, which may be generated upon growing a semiconductor alloy on a semiconductor base material, as is, for instance, the case in conventional threshold adjusting semiconductor alloys for defining specific electronic characteristics in the channel region of P-channel transistors.

Furthermore, in the context of the present disclosure, a “varying” or “graded” concentration profile is to be understood as any type of variation, such as a substantially continuous variation or a step-like variation, in which a pronounced difference of concentration may be determined in two or more “sub-layers” of the semiconductor alloy.

In some illustrative embodiments disclosed herein, the threshold adjusting semiconductor alloy may be formed on the basis of low pressure chemical vapor deposition (LPCVD) techniques in which the semiconductor material under consideration may be selectively grown on a base material, wherein process parameters, such as temperature, gas flow rates, pressure and the like, are appropriately selected so as to suppress significant material deposition on dielectric surface areas, such as silicon dioxide, silicon nitride and the like, while the atomic species may substantially adhere to the semiconductor base material. For example, well-established deposition recipes are available in which a process temperature in the range of approximately 500-900° C. may be applied with a pressure of approximately 1 mTorr-1 Torr, wherein well-established CVD deposition tools may be used in combination with appropriate precursor materials, such as silane, germanium hydride and the like.

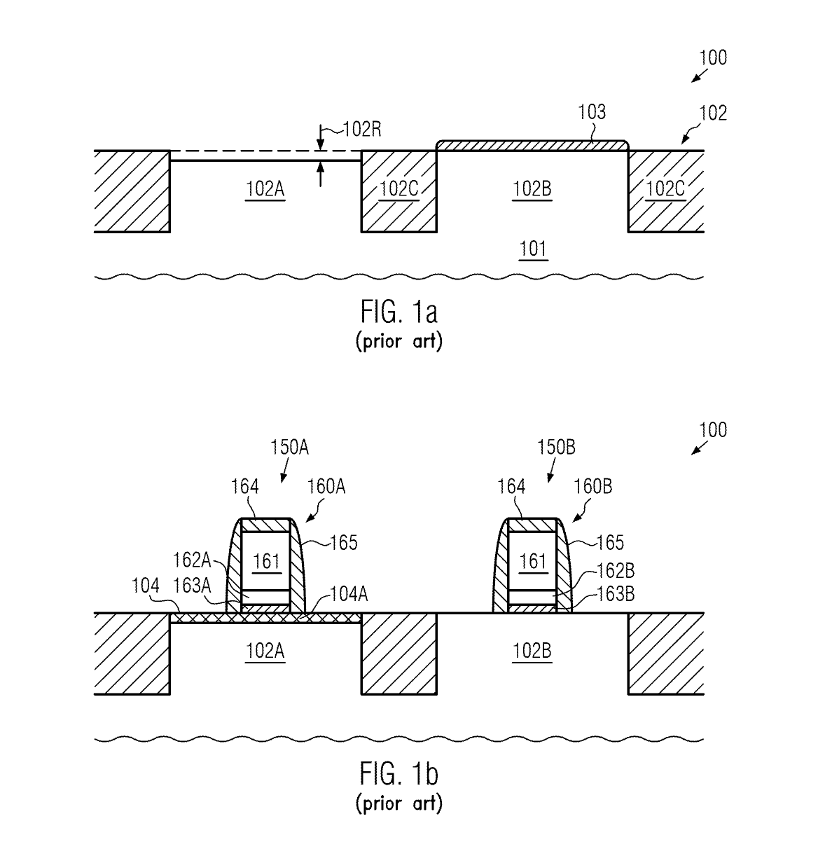

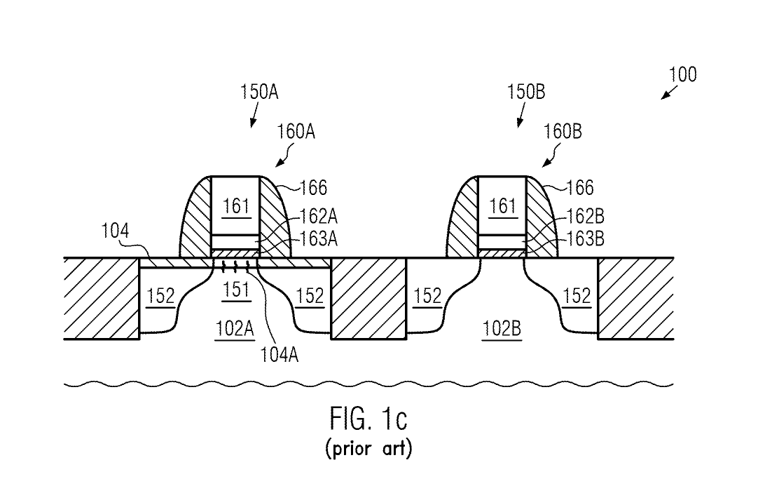

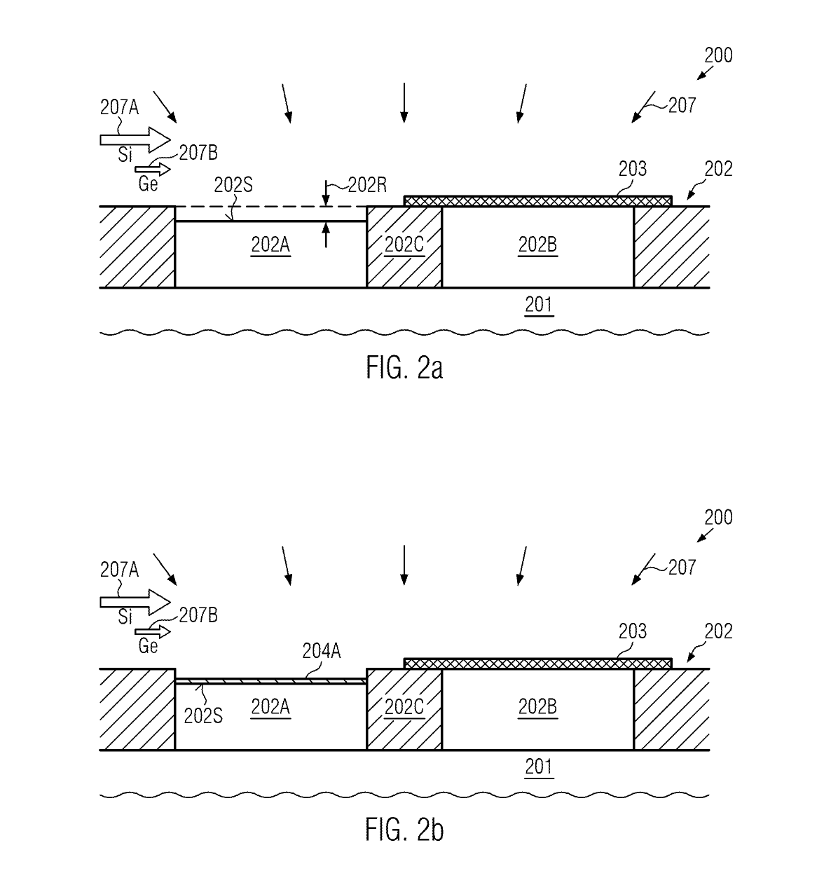

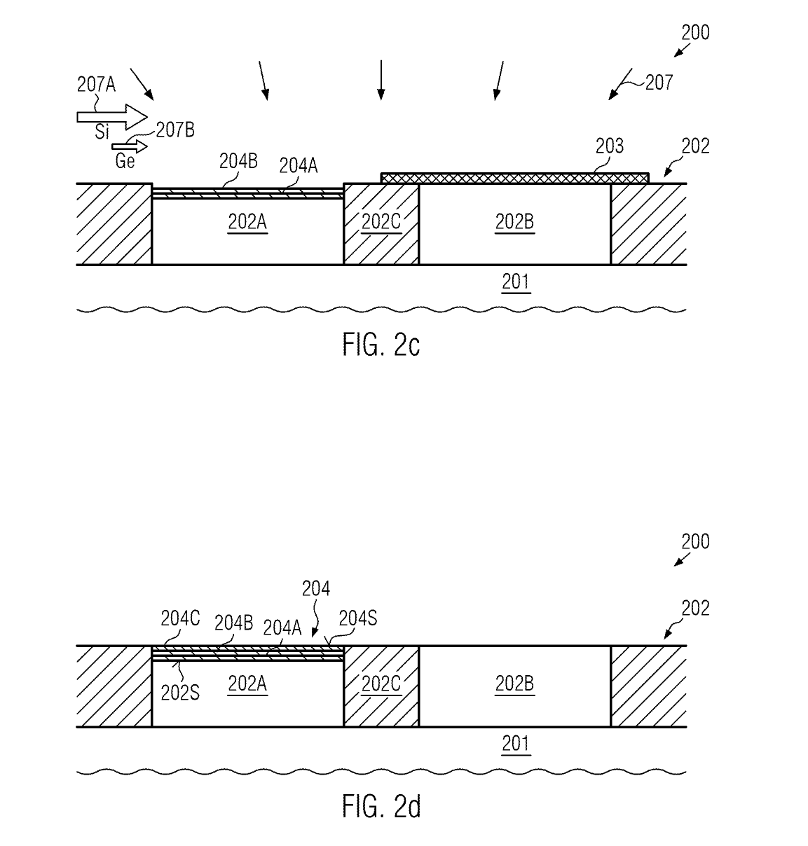

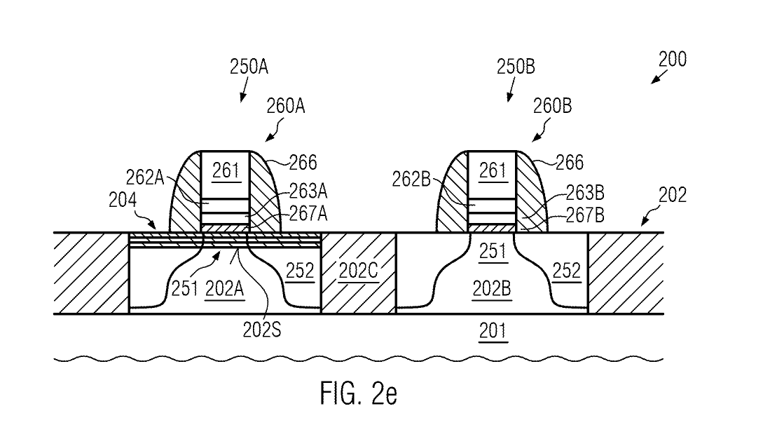

With reference to FIGS. 2a-2e, further illustrative embodiments will now be described in more detail, wherein reference may also be made to FIGS. 1a-1c, if required.

FIG. 2a schematically illustrates a cross-sectional view of a semiconductor device 200 in an early manufacturing stage. As shown, the device 200 may comprise a substrate 201 in combination with a semiconductor layer 202, which, in some illustrative embodiments, may represent a silicon material. Moreover, if an SOI architecture is to be used, a buried insulating material (not shown) may be formed below the semiconductor layer 202. Furthermore, in the manufacturing stage shown, the semiconductor layer 202 may comprise isolation regions 202C, which laterally delineate active regions 202A, 202B, one of which may receive an appropriate semiconductor alloy so as to adjust the electronic characteristics in view of threshold voltage and the like for a field effect transistor to be formed in and above the corresponding active region. In the example shown, an active region 202A may receive a threshold adjusting semiconductor alloy, while an active region 202B may be masked by an appropriate hard mask material 203, such as a silicon dioxide material, a silicon nitride material, amorphous carbon or any combination thereof.

The semiconductor device 200 as shown in FIG. 2a may be formed on the basis of any appropriate process strategy, as is, for instance, also discussed above with reference to the semiconductor device 100. Thus, after forming the active regions 202A, 202B, the hard mask material 203 may be provided according to any appropriate process strategy. For example, material layers may be used which may previously have been provided for forming the isolation structures 202C, while in other cases, in addition or alternatively to this approach, any additional material layers may be deposited or formed by oxidation, depending on the overall process requirements. Thereafter, the corresponding mask layer may be patterned on the basis of appropriate lithography techniques, thereby exposing the active region 202A. Furthermore, in some illustrative embodiments as shown, the active region 202A may be recessed, as indicated by 202R, in order to provide superior growth conditions during the subsequent epitaxial growth process and also to provide an enhanced final surface topography of the active regions 202A, 202B after the formation of the threshold adjusting semiconductor alloy. After the optional recessing of the active region 202A, appropriate cleaning recipes may be applied in order to remove any contaminants, native oxides and the like, which may be accomplished by appropriate wet chemistries, heat treatments and the like. Thereafter, the device 200 is exposed to a deposition atmosphere 207 in order to selectively deposit a semiconductor alloy on the active region 202A. As discussed above, established LPCVD recipes are available for depositing a plurality of semiconductor alloys, such as silicon/germanium, silicon/germanium/tin, gallium arsenide and the like, wherein typically a deposition temperature and process pressure may be applied, as specified above. Furthermore, in the embodiment shown, alloy-forming atomic species 207A, 207B may be applied with a specific concentration within the atmosphere 207 in order to obtain a desired initial material composition upon forming the semiconductor alloy on the exposed surface or interface 202S. In some illustrative embodiments, the species 207A, 207B may represent silicon and germanium in order to form a silicon/germanium alloy with a varying concentration of these alloy-forming species. For example, the precursor gas, such as germanium hydride and the silicon-containing precursor gas, may be provided so as to establish a relatively low germanium concentration in order to form an initial alloy layer having a reduced lattice mismatch with respect to the semiconductor base material, i.e., the material of the surface 202S of the active region 202A. Consequently, during an initial phase of the deposition process 207, relatively non-critical deposition conditions may be established, thereby avoiding the generation of a pronounced number of dislocation defects.

FIG. 2b schematically illustrates the device 200 in an advanced stage of the deposition process 207. As illustrated, a first layer or layer portion 204A may be formed on the surface 202S, which may now represent an interface between the semiconductor base material of the active region 202A and the semiconductor alloy to be formed thereon, wherein the first portion 204A may have an appropriate composition so as to avoid undue generation of dislocation defects, as discussed above. In some illustrative embodiments, the layer 204A may be formed as a silicon/germanium alloy with a germanium concentration of 10 atomic percent and less immediately at the interface 202S. In other cases, the layer 204A may be formed with a germanium concentration of approximately 5 atomic percent and less at the interface 202S. In this respect, it should be appreciated that the interface 202S may be understood as a material layer having a germanium concentration that is 1 atomic percent or less.

In other illustrative embodiments, the layer 204A may have incorporated therein a further atomic species, such as carbon and the like, if considered appropriate for the crystalline quality of the semiconductor alloy at the interface 202S. Furthermore, in some illustrative embodiments, the concentration of the species 207A, 207B may be further varied in this phase of the deposition process 207, for instance in order to increase the concentration of the alloy-forming species having the different covalent radius, such as the germanium species, so as to obtain a further layer or layer portion with a material composition that may be more appropriate for obtaining the finally desired electronic characteristics of a channel region to be formed in the active region 202A. To this end, for example, the gas flow rates of the corresponding precursor materials may be appropriately adjusted by using tool internal control equipment and mechanisms, as are typically available in well-established deposition tools.

FIG. 2c schematically illustrates the semiconductor device 200 in a further advanced manufacturing stage in which a layer or layer portion 204B may be formed on the layer 204A so as to provide a varying or graded concentration profile throughout the thickness of the layers 204A, 204B. As discussed above, the layers 204A and 204B may individually have a substantially constant material composition, however, which may differ from each other in accordance with a desired overall concentration gradient. In other cases, a substantially continuous transition of the concentration may be adjusted within the layers 204A and between the layers 204B, so that, in this case, a corresponding distinction of discrete sub-layers may not be appropriate. In this case, the layers 204A, 204B may represent a resulting thickness of the semiconductor alloy having a varying concentration profile depending on the deposition time, the deposition rate and the varying concentration of the alloy-forming species in the deposition atmosphere. Moreover, in the phase of the deposition process 207 as shown in FIG. 2c, a further variation of the concentration may be achieved by appropriately adjusting the gas flow rates of the species 207A, 207B in order to obtain a desired final thickness and a certain concentration profile in accordance with the overall device requirements.

FIG. 2d schematically illustrates the semiconductor device 200 in a further advanced manufacturing stage. As shown, a threshold adjusting semiconductor material 204 may be formed on the active region 202A, i.e., on the corresponding base material, and hence the layer 204 may now represent a portion of the active region 202A on which a sophisticated gate electrode structure is to be formed. In the example shown in FIG. 2d, three layers 204A, 204B, 204C are illustrated as separate layers, while in other cases the number and the thickness of any such distinguishable layers may vary. In other cases, the transition between hypothetical layers of different concentration may be adjusted in accordance with the deposition recipe so as to obtain any desired concentration gradient and variation throughout the thickness of the layer 204. In some illustrative embodiments, the material composition may be such that the degree of lattice mismatch at a top surface 204S may be greater than a corresponding lattice mismatch at the interface 202S. For example, for a silicon/germanium alloy, the germanium concentration at the top surface 204S may be 30 atomic percent or even higher, while it should be understood that any other desired concentration may be adjusted. In other cases, the concentration may be adjusted such that the degree of lattice mismatch may be low at the interface 202S and may increase towards the top surface 204S, wherein the degree of lattice mismatch may then decrease so as to provide well-defined surface conditions at the surface 204S. For example, the germanium concentration may be low at the interface 202S and may increase to any desired value, for instance up to 30 atomic percent or more, and may subsequently drop so as to provide a germanium concentration of approximately 10 atomic percent or less, or even a germanium concentration of 0, thereby providing a substantially pure silicon surface. In this manner, similar conditions may be obtained for the active regions 202A, 202B for the further processing, for instance for forming a silicon dioxide-based gate dielectric material, possibly in combination with a high-k dielectric material, while nevertheless the graded profile in the layer 204 may provide sufficient flexibility in obtaining a desired threshold voltage.

FIG. 2e schematically illustrates the semiconductor device 200 in a further advanced manufacturing stage. As illustrated, a transistor 250A, which in one illustrative embodiment is a P-channel transistor, may be formed in and above the active region 202A, which comprises the semiconductor alloy 204 having the graded concentration profile. The transistor 250A may comprise drain and source regions 252 in combination with a channel region 251, which is at least partially formed within the layer 204. Furthermore, a gate electrode structure 260A may be formed on the threshold adjusting semiconductor alloy 204 and may comprise a high-k dielectric material 263A in combination with a metal-containing electrode material 262A, followed by a further electrode material 261, such as a semiconductor material and the like. Furthermore, a sidewall spacer structure 266 may be provided in the gate electrode structure 260A, which may be used for defining the lateral and vertical profile of the drain and source regions 252, if formed on the basis of implantation techniques. Similarly, a second transistor 250B may be formed in and above the active region 202B and may represent in one illustrative embodiment an N-channel transistor. Moreover, the drain and source regions 252 in combination with the channel region 251 may be provided in the active region 202B according to the requirements of the transistor 250B. Furthermore, a gate electrode structure 260B may be formed on the active region 202B and may comprise a high-k dielectric material 263B in combination with a metal-containing electrode material 262B and a further electrode material 261. Moreover, the spacer structure 266 may also be provided in the gate electrode structure 260B. It should be appreciated that the transistors 250A, 250B may be formed on the basis of any appropriate process strategy, as is also discussed above with reference to the semiconductor device 100. In particular, the respective threshold voltages may be adjusted on the basis of the materials 263A and/or 262A in combination with the alloy 204 on the one hand, and on the basis of the materials 263B, 262B on the other hand. Furthermore, as previously discussed, in some cases, a conventional dielectric material may be provided, for instance in the form of a silicon oxynitride material and the like, as indicated by 267A, 267B, thereby providing superior interface characteristics for the gate electrode structures 260A, 260B. In some illustrative embodiments, the layers 267A, 267B may be formed on the basis of similar process conditions, for instance when providing an appropriately adapted semiconductor material at the top surface of the layer 204, which may have similar characteristics as the active region 202B. In other cases, the material 267A may be formed on the top surface of the layer 204, which may have a desired high germanium concentration, if a silicon/germanium alloy is considered. Furthermore, due to the superior lattice configuration of the material 204, in particular at the interface 202S, superior uniformity of the transistor characteristic may be achieved, while at the same time yield loss is significantly increased.

As a result, the present disclosure provides semiconductor devices and manufacturing techniques in which the threshold voltage of field effect transistors may be adjusted in combination with sophisticated high-k metal gate electrode structures in an early manufacturing stage by providing a specifically adapted channel semiconductor alloy, which may have a varying concentration profile throughout the thickness of the material, thereby providing superior flexibility in adjusting the overall transistor characteristics, while at the same time the number of dislocation defects may be significantly reduced since the material may be formed with a low lattice mismatch at the interface to the semiconductor base material, while a desired concentration gradient may be adjusted during the further growing of the semiconductor alloy. In this manner, well-established low pressure CVD epitaxy techniques may be applied, while nevertheless obtaining a high degree of flexibility in adjusting the transistor characteristics and avoiding undue yield losses caused by dislocation defects in conventional approaches.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming a crystalline silicon/germanium-containing material on a silicon material of an active region of a P-channel transistor so as to have a graded germanium concentration;
forming a gate electrode structure on said crystalline silicon/germanium-containing material, said gate electrode structure comprising a gate dielectric material separating an electrode material of said gate electrode structure from a channel region in said crystalline silicon/germanium-containing material; and
forming drain and source regions of said P-channel transistor in said active region.

2. The method of claim 1, wherein forming said crystalline silicon/germanium-containing material comprises performing a low pressure chemical vapor deposition epitaxial process and controlling a germanium concentration in a deposition atmosphere of said low pressure chemical vapor deposition epitaxial process so as to form said graded germanium concentration.

3. The method of claim 2, wherein controlling said germanium concentration in said deposition atmosphere comprises adjusting a germanium concentration to approximately 10 atomic percent or less at an initial phase of said deposition process.

4. The method of claim 2, wherein controlling said germanium concentration in said deposition atmosphere comprises adjusting a germanium concentration to approximately 25 atomic percent or higher at a final phase of said deposition process.

5. The method of claim 1, further comprising recessing said active region prior to forming said crystalline silicon/germanium-containing material.

6. The method of claim 1, wherein forming said gate electrode structure comprises forming said gate dielectric material so as to include a high-k dielectric material and forming a metal-containing material on said gate dielectric material.

7. The method of claim 6, wherein said gate electrode structure is formed with a gate length of 50 nm or less.

8. The method of claim 1, wherein forming said silicon/germanium-containing material comprises controlling a thickness so as to be in a range of 8-15 nm.

9. The method of claim 1, further comprising forming a hard mask above an active region of an N-channel transistor and forming said silicon/germanium-containing material in said active region by using said hard mask as a deposition mask.

10. The method of claim 1, further comprising forming a strain-inducing silicon/germanium alloy in said active region after forming said silicon/germanium-containing material.

11. A method of forming a semiconductor device, the method comprising:
forming a hard mask so as to expose an active region of a first transistor and cover an active region of a second transistor;
performing a selective epitaxial growth process so as to form a threshold adjusting semiconductor alloy on said active region of said first transistor with a first lattice mismatch at an interface formed with a surface of said active region of said first transistor and with a second lattice mismatch at a top surface of said threshold adjusting semiconductor alloy, said first lattice mismatch being less than said second lattice mismatch; and
forming a first gate electrode structure on said threshold adjusting semiconductor alloy and forming a second gate electrode structure on said active region of said second transistor.

12. The method of claim 11, wherein said threshold adjusting semiconductor alloy is formed as a silicon/germanium alloy.

13. The method of claim 12, wherein a germanium concentration at said interface is 10 atomic percent or less.

14. The method of claim 12, wherein a germanium concentration at said top surface is 25 atomic percent or higher.

15. The method of claim 11, wherein forming said threshold adjusting semiconductor alloy comprises performing a low pressure chemical vapor deposition process and controlling at least one process parameter so as to adjust a concentration of a lattice mismatch generating species in a deposition atmosphere of said low pressure chemical vapor deposition process.

16. The method of claim 11, wherein forming said first and second gate electrode structures comprises forming a gate dielectric layer so as to include a high-k dielectric material prior to forming drain and source regions of said first and second transistors.

17. A field effect transistor, comprising:
an active region formed above a substrate, said active region comprising a doped semiconductor base material and a threshold adjusting semiconductor alloy, said threshold adjusting semiconductor alloy forming an interface with said semiconductor base material and having a top surface, said threshold adjusting semiconductor alloy comprising a first atomic species and a second atomic species, a concentration of said first and second atomic species varying between said interface and said top surface;
a gate electrode structure formed on said threshold adjusting semiconductor material, said gate electrode comprising a high-k dielectric material; and
drain and source regions formed in said active region.

18. The field effect transistor of claim 17, wherein said threshold adjusting semiconductor alloy is a silicon/germanium alloy.

19. The field effect transistor of claim 18, wherein a germanium concentration at said interface is 10 atomic percent or less and said germanium concentration at said top surface is 25 atomic percent or higher.

20. The field effect transistor of claim 19, wherein a thickness of said threshold adjusting semiconductor alloy is 15 nm or less.
